(19) United States
(12) Patent Application Publication
(10) Pub. No.: US 2015/0200039 A1
(43) Pub. Date: Jul. 16, 2015

(54) CONDUCTIVE MATERIAL AND TRANSDUCER INCLUDING THE CONDUCTIVE MATERIAL

(71) Applicant: SUMITOMO RIKO COMPANY LIMITED, Aichi-ken (JP)

(72) Inventors: Yutaro TAGUCHI, Aichi-ken (JP); Jun KOBAYASHI, Aichi-ken (JP); Hitoshi YOSHIKAWA, Aichi-ken (JP)

(73) Assignee: SUMITOMO RIKO COMPANY LIMITED, Aichi-ken (JP)

(21) Appl. No.: 14/667,862

(22) Filed: Mar. 25, 2015

Related U.S. Application Data
(63) Continuation of application No. PCT/JP2013/083588, filed on Dec. 16, 2013.

(30) Foreign Application Priority Data
Dec. 17, 2012 (JP) 2012-274504

(51) Int. Cl. H01B 1/24; H01L 41/047

(52) U.S. Cl. CPC H01B 1/24; H01L 41/0478

(57) ABSTRACT

A conductive material includes an elastomer and a conductive agent contained in the elastomer. The elastomer has a crosslinked structure through a slide-ring molecule having a ring molecule and a linear molecule that passes through an opening of the ring molecule and is included in the ring molecule. At least a part of polymer chains of the elastomer is crosslinked with the ring molecule, and as the ring molecule moves along the linear molecule, a crosslinking point moves. A transducer includes an electrostrictive layer made of a polymer, a plurality of electrodes with the electrostrictive layer interposed therebetween, and wirings connecting to the electrodes, respectively. In the transducer, either one or both of the electrodes and the wirings are formed of the conductive material.

### TECHNICAL FIELD

The present invention relates to a conductive material preferably used for electrodes, wirings, and other members of flexible transducers produced with polymer materials.

### BACKGROUND ART

Highly flexible electrostrictive transducers have been developed by using polymer materials such as elastomers. Such a transducer includes a dielectric layer made of an elastomer between a pair of electrodes, for example. When the voltage applied between a pair of electrodes increases, the electrostatic attraction between the electrodes increases. This compresses the dielectric layer interposed between the electrodes in the thickness direction, reducing the thickness of the dielectric layer. When the thickness of the dielectric layer decreases, the dielectric layer accordingly extends in the parallel direction to the electrode face. In contrast, when the voltage applied between the pair of electrodes decreases, the electrostatic attraction between the electrodes decreases. This reduces the compressive force against the dielectric layer in the thickness direction, and the thickness of the dielectric layer increases due to the elastic restoring force of the dielectric layer. When the thickness of the dielectric layer increases, the dielectric layer accordingly contracts in the parallel direction to the electrode face. On this account, in a flexible transducer, electrodes and wirings are required to have elasticity so as to follow deformation of the dielectric layer. Elastic conductive materials can be produced by adding a conductive agent such as metal fillers to an elastomer as described in Patent Documents 1 and 2, for example.

### RELATED ART DOCUMENTS

### Patent Documents

Patent Document 1: Japanese Patent Application Publication No. 2012-138260 (JP 2012-138260 A)

Patent Document 2: Japanese Patent Application Publication No. 2010-153364 (JP 2010-153364 A)

Patent Document 3: Japanese Patent Application Publication No. 2009-124875 (JP 2009-124875 A)

Patent Document 4: Japanese Patent Application Publication No. 2010-86864 (JP 2010-86864 A)

Patent Document 5: Japanese Patent Application Publication No. 2011-241401 (JP 2011-241401 A)

### SUMMARY OF THE INVENTION

### Problem to be Solved by the Invention

As a matrix for elastic conductive materials, crosslinked rubber or a thermoplastic elastomer is used. The crosslinked rubber has excellent elasticity and bending properties but has fixed crosslinking points, and thus stress caused by extension or bending is likely to be concentrated on the crosslinking points. On this account, a deformation may lead to the breakage of conductive pathways or destruction of the material itself. Thermoplastic elastomers without any crosslinking point are likely to lose their resilience, to become cracked, or the like when extension and contraction or bending is repeated. The thermoplastic elastomers thus may cause the breakage of conductive pathways or the destruction of the material as with the crosslinked rubber. Hence, the conductive material including an elastomer as the matrix has problems of the deterioration of the electric conductivity and the destruction of the material at the time of deformation.

In view of the above circumstances, an object of the present invention is to provide a conductive material having an electric conductivity that is less likely to decrease at the time of extension, and having excellent durability. Another object of the present invention is to provide a transducer having excellent durability by using the conductive material.

### Means for Solving the Problem

(1) In order to solve the problem, a conductive material of the present invention is characterized by including an elastomer and a conductive agent contained in the elastomer. The elastomer has a crosslinked structure through a slide-ring molecule having a ring molecule and a linear molecule that passes through an opening of the ring molecule and is included in the ring molecule. At least a part of polymer chains of the elastomer is crosslinked with the ring molecule. As the ring molecule moves along the linear molecule, a crosslinking point moves.

The matrix of the conductive material of the present invention is an elastomer. The elastomer includes a crosslinked rubber and a thermoplastic elastomer. The elastomer has a crosslinked structure through a slide-ring molecule. In other words, as long as the elastomer has the crosslinked structure through the slide-ring molecule, the polymer chains of the elastomer may be crosslinked with each other or may not be crosslinked with each other.

The slide-ring molecule has a ring molecule and a linear molecule. The linear molecule passes through the opening of the ring molecule in a skewer shape and is included in the ring molecule. At each end of the linear molecule, a blocking group may be bonded so that the ring molecules are not eliminated. The ring molecule can move along the linear molecule. In the conductive material of the present invention, at least a part of polymer chains of the elastomer is crosslinked with the ring molecules. This structure enables the movement of the crosslinking points together with the ring molecules. In the conductive material of the present invention, the crosslinking points thus move at the time of deformation such as extension, contraction, and bending. This movement reduces stress concentration in the elastomer, and consequently suppresses the breakage of conductive pathways or the destruction of the material itself at the time of deformation. The conductive material has the crosslinked structure and thus is less likely to lose their resilience, to become cracked, or the like even when extension and contraction or bending is repeated. The conductive material of the present invention therefore has an electric conductivity that is less likely to decrease at the time of extension and also has high durability. In addition, the conductive material has larger extensibility due to the dispersed stress.

Patent Documents 3 and 4 describe a dielectric layer formed from polyrotaxane, which is a slide-ring molecule. In addition, Patent Document 5 describes a material in which two polyrotaxanes are crosslinked through respective ring molecules. However, the materials described in Patent Documents 3 to 5 are formed by crosslinking the slide-ring molecules with each other, rather than crosslinking a slide-ring molecule with an elastomer polymer. In addition, the materials contain no conductive agent.

(2) A transducer of the present invention is characterized by including an electrostrictive layer made of a polymer, a plurality of electrodes with the electrostrictive layer interposed therebetween, and wirings connecting to the corresponding electrodes, in which either one or both of the electrodes and the wirings are formed of the conductive material (1) of the present invention.

A transducer is an apparatus that converts a type of energy to another type of energy. The transducer is exemplified by transducers that perform the conversion between mechanical energy and electric energy, such as actuators, sensors, and power generation devices, and transducers that perform the conversion between acoustic energy and electric energy, such as speakers and microphones. Electrodes and wirings formed from the conductive material of the present invention are flexible and have excellent elasticity. Thus, in the transducer of the present invention, the movement of the electrostrictive layer is less likely to be restricted by the electrodes or wirings. The electrodes and the wirings have high electric conductivity and have an electrical resistance that is less likely to increase even when the electrodes and the wirings are extended. In addition, the electrodes and the wirings are less likely to be broken even when extension and contraction or bending is repeated. On this account, the transducer of the present invention has a performance that is unlikely to deteriorate due to the electrodes or the wirings. The transducer of the present invention therefore has excellent durability.

### BRIEF DESCRIPTION OF THE DRAWINGS

FIG. 1A and FIG. 1B show schematic sectional views of an actuator as a first embodiment of a transducer of the present invention. FIG. 1A shows the actuator in the voltage-OFF state, and FIG. 1B shows the actuator in the voltage-ON state.

FIG. 2 is a top view of a capacitance sensor as a second embodiment of the transducer of the present invention.

FIG. 3 is a sectional view taken along line III-III in FIG. 2.

FIG. 4A and FIG. 4B show schematic sectional views of a power generation device as a third embodiment of the transducer of the present invention. FIG. 4A shows the power generation device extended, and FIG. 4B shows the power generation device contracted.

FIG. 5 is a perspective view of a speaker as a fourth embodiment of the transducer of the present invention.

FIG. 6 is a sectional view taken along line VI-VI in FIG. 5.

### DESCRIPTION OF THE REFERENCE NUMERALS

1: actuator (transducer); 10: dielectric layer (electrostrictive layer); 11a, 11b: electrode; 12a, 12b: wiring; 13: power source
2: capacitance sensor (transducer); 20: dielectric layer; 21a, 21b: electrode; 22a, 22b: wiring; 23a, 23b: cover film; 24: connector
3: power generation device (transducer); 30: dielectric layer; 31a, 31b: electrode; 32a to 32c: wiring
4: speaker (transducer); 40a: first outer frame; 40b: second outer frame; 41a: first inner frame; 41b: second inner frame; 42a: first dielectric layer; 42b: second dielectric layer; 43a: first outer electrode; 43b: second outer electrode; 44a: first inner electrode; 44b: second inner electrode; 45a: first diaphragm; 45b: second diaphragm; 430a, 430b, 440a, 440b: terminal; 460: bolt; 461: nut; 462: spacer

### MODES FOR CARRYING OUT THE INVENTION

Embodiments of a conductive material and a transducer of the present invention will be described hereinafter. The conductive material and the transducer of the present invention are not limited to the embodiments below, and various modifications, improvements, and other changes may be made thereto by a person skilled in the art without departing from the scope of the present invention.

<Conductive Material>

A conductive material of the present invention includes an elastomer and a conductive agent contained in the elastomer. The elastomer can be appropriately selected in consideration of flexibility in a use environment, tackiness to a mating member, or other properties. For example, an elastomer having a glass transition temperature (Tg) of 0° C. or less is preferably used. The elastomer more preferably has a Tg of −20° C. or less, and even more preferably −35° C. or less. In the present specification, Tg is an intermediate glass transition temperature determined in accordance with JIS K7121 (1987).

Specifically, the elastomer is preferably acrylic rubber, silicone rubber, urethane rubber, urea rubber, fluororubber, or various thermoplastic elastomers. Among them, acrylic rubber is preferred because it exhibits excellent tackiness to an electrostrictive layer made of nitrile rubber when a transducer is produced and contains ionic impurities in small amounts.

The elastomer has a crosslinked structure through a slide-ring molecule. As described above, when the elastomer has the crosslinked structure through the slide-ring molecule, the polymer chains of the elastomer may be crosslinked with each other or may not be crosslinked with each other. The slide-ring molecule has a ring molecule and a linear molecule that passes through the opening of the ring molecule and is included in the ring molecule. The slide-ring molecule is preferably polyrotaxane.

The type of the ring molecule is not particularly limited. Examples of the ring molecule include α-cyclodextrin, β-cyclodextrin, and γ-cyclodextrin. The ring molecule preferably has a reactive group such as an epoxy group, a glycidyl group, —OH, —SH, —NH₂, —COOH, —SO₃H, and —PO₄H so as to be crosslinked with a raw material polymer of the elastomer. For example, some of —OH of α-cyclodextrin or other ring molecules may be replaced with another reactive group. α-Cyclodextrin or other ring molecules may be chemically modified. For the chemical modification, a reactive group such as an acetyl group, a propionyl group, a hexanoyl group, a methyl group, an ethyl group, a propyl group, a 2-hydroxypropyl group, a 1,2-dihydroxypropyl group, a cyclohexyl group, a butylcarbamoyl group, a hexylcarbamoyl group, a phenyl group, a caprolactone group, an alkoxysilane group, an acryloyl group, a methacryloyl group, and a cinnamoyl group can be bonded to the ring molecule. A polymer chain such as polycaprolactone and polycarbonate may be bonded directly or through the reactive group.

The type of the linear molecule is not particularly limited. Examples of the linear molecule include hydrophilic polymers such as polyvinyl alcohol, polyvinylpyrrolidone, poly(meth)acrylic acid, cellulose resins (including carboxymethylcellulose, hydroxyethylcellulose, and hydroxypropylcellulose), polyacrylamide, polyethylene oxide, polyethylene glycol, polypropylene glycol, polyvinyl acetal resins, polyvinyl methyl ether, polyamine, polyethyleneimine, casein, gelatin, and starch. Among them, polyethylene glycol is preferred.

At each end of the linear molecule, a blocking group may be bonded so that the ring molecules are not eliminated. Examples of the blocking group include dinitrophenyl groups, cyclodextrins, adamantane groups, trityl groups, fluoresceins, silsesquioxanes, pyrenes, substituted benzenes, optionally substituted polynuclear aromatics, and steroids.

The type of the conductive agent contained in the elastomer is not particularly limited. The conductive agent may be appropriately selected from particles of metal such as silver, gold, copper, nickel, rhodium, palladium, chromium, titanium, platinum, iron, and alloys of them; nanowires of metal such as silver, gold, copper, platinum, and nickel; and electrically conductive carbon materials such as carbon black, carbon nanotubes, graphite, and graphene. The conductive agent may be particles coated with metal, such as silver-coated copper particles. For example, when nonmetal particles coated with metal are used, such a conductive agent has a smaller specific gravity than that of a conductive agent composed of metal alone. In a paint containing such a conductive agent, the conductive agent can be prevented from settling and has higher dispersibility. In addition, processed particles facilitate production of conductive agents in various forms and can reduce the cost of the conductive agent. The metal used for coating may be the metal materials exemplified above, such as silver. Particles other than metal particles may be made of a carbon material such as carbon black; a metal oxide such as calcium carbonate, titanium dioxide, aluminum oxide, and barium titanate; an inorganic substance such as silica; or a resin such as acrylic resins and urethane resins. A single conductive agent may be used, or two or more conductive agents may be used as a mixture.

The size, shape, etc. of the conductive agent are not particularly limited. For example, when the conductive agent has a large aspect ratio, conductive pathways are readily formed. Thus, an intended electric conductivity can be achieved even when the conductive agent is contained in a smaller amount. Such a conductive material can obtain higher flexibility. From such viewpoints, the conductive agent preferably has an aspect ratio of 30 or more. The aspect ratio can be determined by dividing the average length in the longitudinal direction of a conductive agent by the average length in the transverse direction of a conductive agent. A material having structured morphology, such as carbon black, can also achieve an intended electric conductivity even when contained in a comparatively small amount.

The conductive material may contain additives such as crosslinking agents, crosslinking promoters, crosslinking aids, dispersants, reinforcements, plasticizers, age inhibitors, and colorants, as necessary, in addition to the elastomer (including the slide-ring molecule) and the conductive agent. The crosslinking agent, the crosslinking promoter, the crosslinking aid, and other agents contributing to crosslinking reaction can be appropriately selected depending on the type of the elastomer and the slide-ring molecule, for example.

The conductive material can be produced as follows, for example: First, a raw material polymer of the elastomer is dissolved in a solvent; to the polymer solution, the conductive agent, the slide-ring molecule, and, if necessary, additives such as a crosslinking agent are added; and the whole is stirred and mixed to prepare a conductive paint. Next, the prepared conductive paint is applied to a substrate; and the coating is cured by heating, for example. A slide-ring molecule material containing the slide-ring molecule and a crosslinking agent may be used as the slide-ring molecule.

As the method of applying the conductive paint, various known methods may be used. Examples of the method include printing methods such as inkjet printing, flexo printing, gravure printing, screen printing, pad printing, and lithography; dipping; spraying; and bar coating. For example, when the printing method is employed, a coated area and a non-coated area can be separately formed easily, and large areas, fine lines, and complicated shapes can be easily printed. Among the printing methods, screen printing is preferred because a paint having high viscosity can be used and the coating thickness can be easily adjusted.

The conductive material of the present invention is formed on the surface of various substrates including an electrostrictive layer depending on the intended application. Examples of the substrate include flexible resin sheets made from polyimide, polyethylene, polyethylene terephthalate (PET), polyethylene naphthalate (PEN), and similar resins; and elastic elastomer sheets. Examples of the elastomer include acrylic rubber, ethylene-propylene-diene copolymers (EPDM), nitrile rubber, urethane rubber, butyl rubber, silicone rubber, chloroprene rubber, ethylene-vinyl acetate copolymers, and thermoplastic elastomers (olefinic elastomers, styrenic elastomers, polyester elastomers, acrylic elastomers, urethane elastomers, and polyvinyl chloride elastomers).

<Transducer>

A transducer of the present invention includes an electrostrictive layer made of a polymer, a plurality of electrodes with the electrostrictive layer interposed therebetween, and wirings connecting to the corresponding electrodes. In the transducer of the present invention, the number of the electrostrictive layers may be one or two or more. For example, the electrostrictive layer may be formed by stacking a dielectric layer, a high-resistivity layer, an ion-containing layer, or the like. The transducer of the present invention may have a multilayer structure in which electrostrictive layers and electrodes are alternately stacked.

The electrostrictive layer is made of a polymer. Here, the term “made of a polymer” means that the base material of the electrostrictive layer is a resin or an elastomer. Thus, the electrostrictive layer may contain other components in addition to the elastomer or resin component.

The elastomer has excellent elasticity and thus is preferred. In order to increase the displacement and the generative force, specifically, an elastomer having a high relative dielectric constant is preferably used. Specifically, the elastomer preferably has a relative dielectric constant (100 Hz) at normal temperature of 2 or more and more preferably 5 or more. For example, the elastomer preferably has a polar functional group such as an ester group, a carboxy group, a hydroxy group, a halogen group, an amido group, a sulfone group, a urethane group, and nitrile group. Alternatively, the elastomer preferably contains a low molecular weight polar compound having such a polar functional group. Preferred examples of the elastomer include silicone rubber, nitrile rubber (NBR), hydrogenated nitrile rubber (H-NBR), EPDM, acrylic rubber, urethane rubber, epichlorohydrin rubber, chlorosulfonated polyethylene, and chlorinated polyethylene.

The thickness of the electrostrictive layer can be appropriately selected depending on the intended application of the transducer. For example, for an actuator, the electrostrictive layer preferably has a small thickness in view of downsizing, lower-potential driving, and a larger displacement. In this case, the electrostrictive layer preferably has a thickness of 1 μm or more and 1,000 μm (1 mm) or less in consideration of dielectric breakdown, etc. The thickness is more preferably 5 μm or more and 200 μm or less.

In the transducer of the present invention, either one or both of the electrodes and the wirings are formed of the conductive material of the present invention. The structure and the production method of the conductive material of the present invention are as described above, and thus are not described here. In the electrodes and the wirings of the transducer of the present invention, the preferred embodiment of the conductive material of the present invention is preferably employed. Embodiments of an actuator, a capacitance sensor, a power generation device, and a speaker will next be described as embodiments of the transducer of the present invention.

### First Embodiment

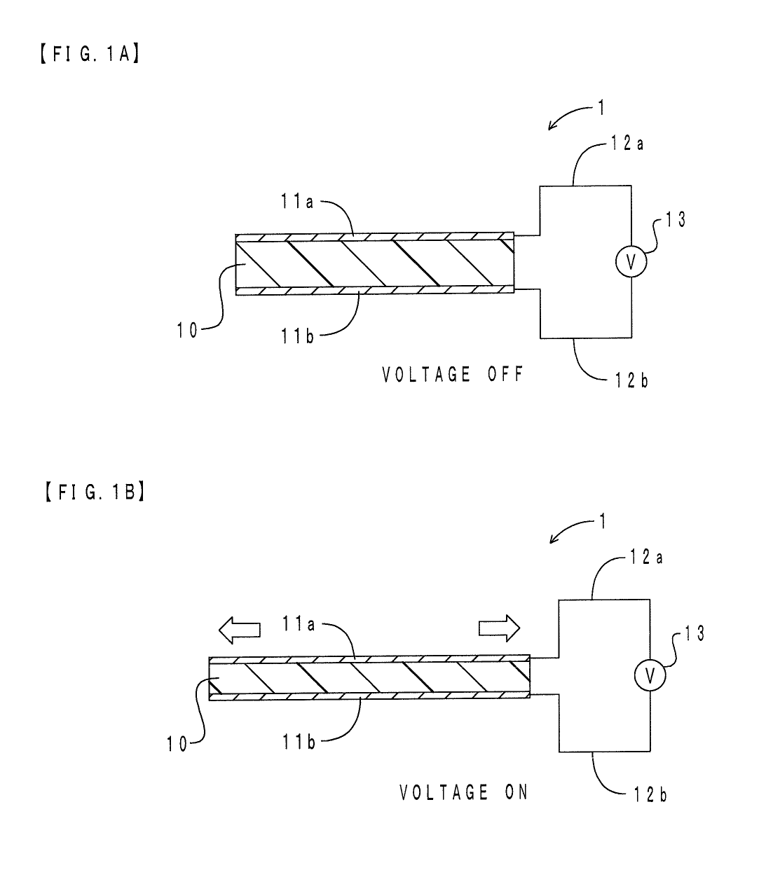

An embodiment of an actuator will be described as a first embodiment of the transducer of the present invention. FIG. 1A and FIG. 1B show schematic sectional views of an actuator of the present embodiment. FIG. 1A shows the actuator in the voltage OFF state, and FIG. 1B shows the actuator in the voltage ON state.

As shown in FIG. 1A and FIG. 1B, an actuator 1 includes a dielectric layer 10, electrodes 11a, 11b, and wirings 12a, 12b. The dielectric layer 10 is made of silicone rubber. The dielectric layer 10 is included in the electrostrictive layer of the present invention. The electrode 11a is arranged so as to cover substantially the whole top face of the dielectric layer 10. Similarly, the electrode 11b is arranged so as to cover substantially the whole bottom face of the dielectric layer 10. The electrodes 11a, 11 b are connected to a power source 13 through the wirings 12a, 12b, respectively. The electrodes 11a, 11b are made of the conductive material of the present invention.

To switch the actuator from the OFF state to the ON state, a voltage is applied between the pair of electrodes 11a, 11b. The application of the voltage reduces the thickness of the dielectric layer 10, and the dielectric layer 10 accordingly extends in the parallel direction to the faces of the electrodes 11a, 11b as shown by the white arrows in FIG. 1B. Accordingly, the actuator 1 outputs a drive force in the up-down direction and the left-right direction in the drawings.

According to the present embodiment, the electrodes 11a, 11b are flexible and have excellent elasticity. On this account, the movement of the dielectric layer 10 is less likely to be restricted by the electrodes 11a, 11b. Thus, the actuator 1 can provide a large force and displacement. In addition, the electrodes 11a, 11b have high electric conductivity and also have an electrical resistance that is less likely to increase even when the electrodes 11a, 11 b are extended. The electrodes 11a, 11b are less likely to lose their resilience, to become cracked, or the like even when extension and contraction are repeated. On this account, deterioration in performance of the actuator 1 due to the electrodes 11a, 11 b is less likely to occur. The actuator 1 therefore has excellent durability.

### Second Embodiment

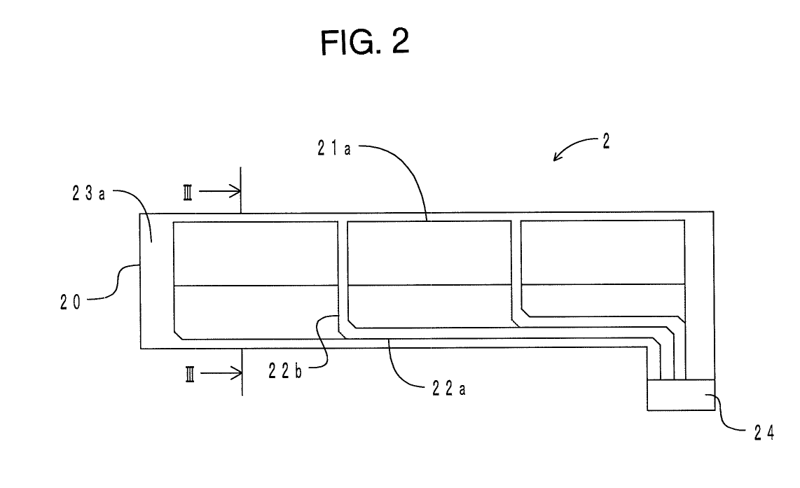

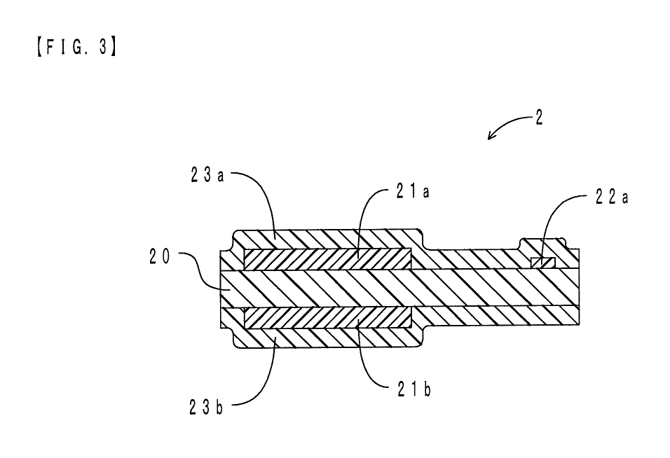

An embodiment of a capacitance sensor will next be described as a second embodiment of the transducer of the present invention. First, the configuration of a capacitance sensor in the present embodiment will be described. FIG. 2 is a top view of the capacitance sensor. FIG. 3 is a sectional view taken along line III-III in FIG. 2. As shown in FIG. 2 and FIG. 3, a capacitance sensor 2 includes a dielectric layer 20, a pair of electrodes 21a, 21b, wirings 22a, 22b, and cover films 23a, 23b.

The dielectric layer 20 is made of H-NBR and has a strip shape extending in the left-right direction. The dielectric layer 20 has a thickness of about 300 μm. The dielectric layer 20 is included in the electrostrictive layer of the present invention.

The electrode 21a has a rectangular shape. Three electrodes 21a are formed on the top face of the dielectric layer 20 by screen printing. Similarly, the electrode 21b has a rectangular shape. Three electrodes 21b are formed on the bottom face of the dielectric layer 20 so as to face the electrodes 21a with the dielectric layer 20 interposed therebetween. The electrodes 21b are formed on the bottom face of the dielectric layer 20 by screen printing. In this manner, three pairs of the electrodes 21a, 21b are disposed with the dielectric layer 20 interposed therebetween. The electrodes 21a, 21b are made of the conductive material of the present invention.

The wirings 22a are connected to the corresponding electrodes 21a formed on the top face of the dielectric layer 20. The wiring 22a connects the electrode 21a to a connector 24. The wirings 22a are formed on the top face of the dielectric layer 20 by screen printing. Similarly, the wirings 22b are connected to the corresponding electrodes 21b formed on the bottom face of the dielectric layer 20 (in FIG. 2, shown by dotted lines). The wiring 22b connects the electrode 21b to a connector (not shown). The wirings 22b are formed on the bottom face of the dielectric layer 20 by screen printing. The wirings 22a, 22b are made of the conductive material of the present invention.

The cover film 23a is made of acrylic rubber and has a strip shape extending in the left-right direction. The cover film 23a covers the top faces of the dielectric layer 20, the electrodes 21a, and the wirings 22a. Similarly, the cover film 23b is made of acrylic rubber and has a strip shape extending in the left-right direction. The cover film 23b covers the bottom faces of the dielectric layer 20, the electrodes 21b, and the wirings 22b.

Next, the movement of the capacitance sensor 2 will be described. For example, when the capacitance sensor 2 is pushed from above, the dielectric layer 20, the electrodes 21a, and the cover film 23a are monolithically bent downward. The compression reduces the thickness of the dielectric layer 20. Consequently, the capacitance between the electrodes 21a, 21b becomes large. A deformation by the compression can be detected on the basis of a change in the capacitance.

Next, advantageous effects of the capacitance sensor 2 will be described. According to the present embodiment, the electrodes 21a, 21b and the wirings 22a, 22b are flexible and have excellent elasticity. On this account, the movement of the dielectric layer 20 is less likely to be restricted by the electrodes 21a, 21b and the wirings 22a, 22b. The capacitance sensor 2 thus has good responsivity. In addition, the electrodes 21a, 21b and the wirings 22a, 22b have high electric conductivity, also have an electrical resistance that is less likely to increase even when the electrodes 21a, 21b and the wirings 22a, 22b are extended, and are less likely to lose their resilience, to become cracked, or the like even when extension and contraction are repeated. Thus, deterioration in performance of the capacitance sensor 2 due to the electrodes 21a, 21b and the wirings 22a, 22b is less likely to occur. The capacitance sensor 2 therefore has excellent durability. The capacitance sensor 2 includes three pairs of electrodes 21a, 21b, in which each pair of electrodes 21a, 21b face each other with the dielectric layer 20 interposed therebetween. The number, size, shape, arrangement, and the like of the electrodes can be appropriately selected depending on the intended application.

### Third Embodiment

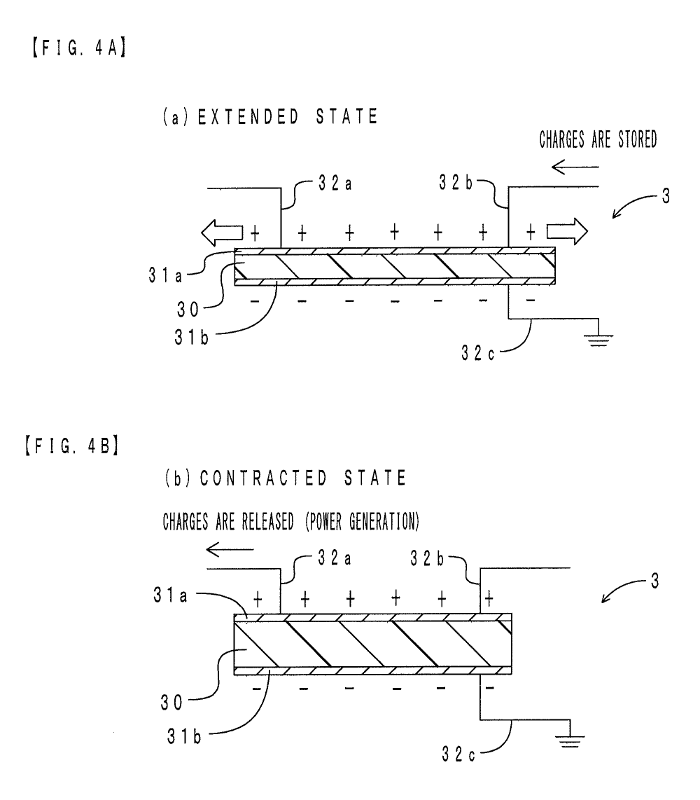

An embodiment of a power generation device will be described as a third embodiment of the transducer of the present invention. FIG. 4A and FIG. 4B show schematic sectional views of a power generation device of the present embodiment. FIG. 4A shows the power generation device extended, and FIG. 4B shows the power generation device contracted.

As shown in FIG. 4A and FIG. 4B, a power generation device 3 includes a dielectric layer 30, electrodes 31a, 31b, and wirings 32a to 32c. The dielectric layer 30 is made of H-NBR. The dielectric layer 30 is included in the electrostrictive layer of the present invention. The electrode 31a is arranged so as to cover substantially the whole top face of the dielectric layer 30. Similarly, the electrode 31b is arranged so as to cover substantially the whole bottom face of the dielectric layer 30. To the electrode 31a, the wirings 32a, 32b are connected. In other words, the electrode 31a is connected to an external load (not shown) through the wiring 32a. The electrode 31a is also connected to a power source (not shown) through the wiring 32b. The electrode 31b is grounded through the wiring 32c. The electrodes 31a, 31b are made of the conductive material of the present invention.

As shown by the white arrows in FIG. 4A, when the power generation device 3 is compressed to extend the dielectric layer 30 in the parallel direction to the faces of the electrodes 31a, 31b, the thickness of the dielectric layer 30 decreases, and charges are stored between the electrodes 31a, 31b. Subsequently, when the compressive force is removed, the dielectric layer 30 contracts by the elastic restoring force of the dielectric layer 30 and has a larger thickness as shown in FIG. 4B. At that time, the stored charges are discharged through the wiring 32a.

According to the present embodiment, the electrodes 31a, 31b are flexible and have excellent elasticity. On this account, the movement of the dielectric layer 30 is less likely to be restricted by the electrodes 31a, 31b. In addition, the electrodes 31a, 31b have high electric conductivity and also have an electrical resistance that is less likely to increase even when the electrodes 31a, 31b are extended. The electrodes 31a, 31b are less likely to lose their resilience, to become cracked, or the like even when extension and contraction are repeated. Thus, deterioration in performance of the power generation device 3 due to the electrodes 31a, 31b is less likely to occur. The power generation device 3 therefore has excellent durability.

### Fourth Embodiment

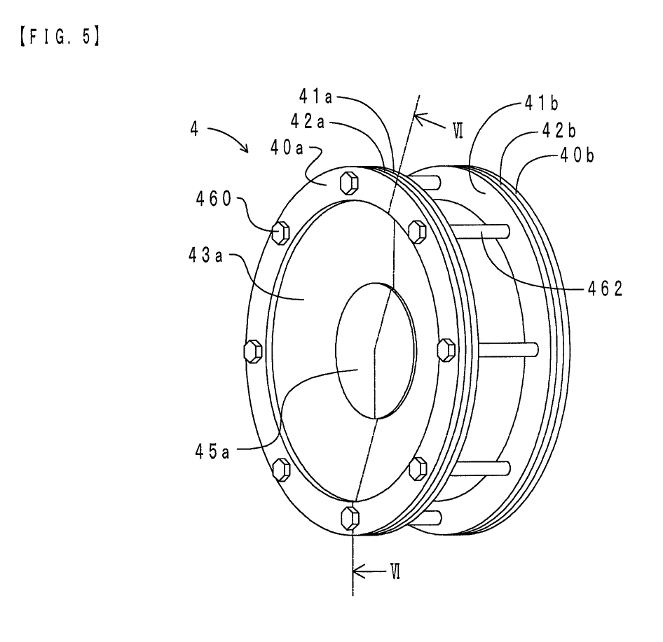

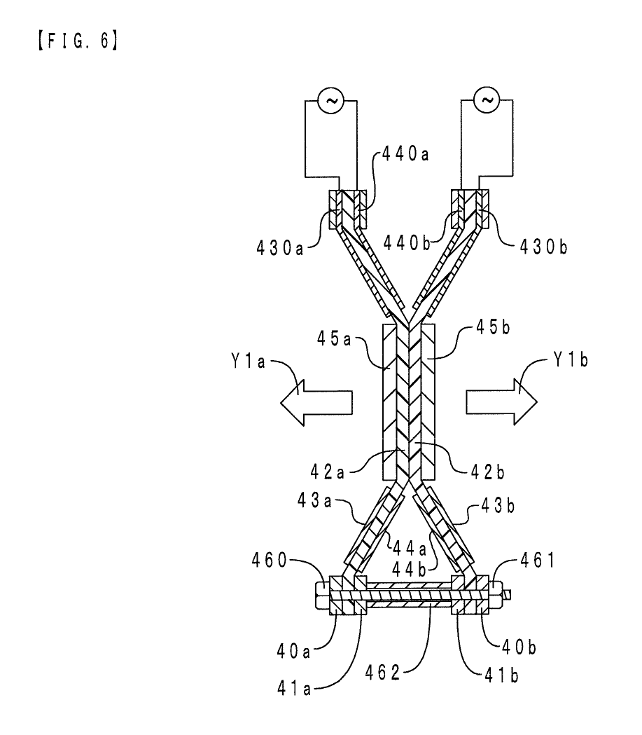

An embodiment of a speaker will be described as a fourth embodiment of the transducer of the present invention. First, the configuration of the speaker in the present embodiment will be described. FIG. 5 is a perspective view of the speaker of the present embodiment. FIG. 6 is a sectional view taken along line VI-VI in FIG. 5. As shown in FIG. 5 and FIG. 6, a speaker 4 includes a first outer frame 40a, a first inner frame 41a, a first dielectric layer 42a, a first outer electrode 43a, a first inner electrode 44a, a first diaphragm 45a, a second outer frame 40b, a second inner frame 41b, a second dielectric layer 42b, a second outer electrode 43b, a second inner electrode 44b, a second diaphragm 45b, eight bolts 460, eight nuts 461, and eight spacers 462.

Each of the first outer frame 40a and the first inner frame 41a is made of a resin and has a ring shape. The first dielectric layer 42a is made of H-NBR and has a circular, thin film-like shape. The first dielectric layer 42a is stretched between the first outer frame 40a and the first inner frame 41a. In other words, the first dielectric layer 42a is sandwiched and fixed by the first outer frame 40a at the front side and the first inner frame 41a at the back side while maintaining a predetermined tension. The first dielectric layer 42a is included in the electrostrictive layer of the present invention. The first diaphragm 45a is made of a resin and has a disk shape. The first diaphragm 45a has a smaller diameter than that of the first dielectric layer 42a. The first diaphragm 45a is arranged at substantially the center of the front face of the first dielectric layer 42a.

The first outer electrode 43a has a ring shape. The first outer electrode 43a is affixed on the front face of the first dielectric layer 42a. The first inner electrode 44a also has a ring shape. The first inner electrode 44a is affixed on the back face of the first dielectric layer 42a. The first outer electrode 43a and the first inner electrode 44a are arranged back-to-back with the first dielectric layer 42a interposed therebetween. Both the first outer electrode 43a and the first inner electrode 44a are made of the conductive material of the present invention. As shown in FIG. 6, the first outer electrode 43a has a terminal 430a, and the first inner electrode 44a has a terminal 440a. To the terminals 430a, 440a, a voltage is applied from outside.

The configurations, the materials, and the shapes of the second outer frame 40b, the second inner frame 41b, the second dielectric layer 42b, the second outer electrode 43b, the second inner electrode 44b, and the second diaphragm 45b (hereinafter collectively called “second members”) are the same as those of the first outer frame 40a, the first inner frame 41a, the first dielectric layer 42a, the first outer electrode 43a, the first inner electrode 44a, and the first diaphragm 45a (hereinafter collectively called “first members”). The first members and the second members are arranged so as to be symmetric with respect to the front-back direction. The arrangement will be briefly described. The second dielectric layer 42b is made of H-NBR and is stretched between the second outer frame 40b and the second inner frame 41b. The second dielectric layer 42b is included in the electrostrictive layer of the present invention. The second diaphragm 45b is arranged at substantially the center of the front face of the second dielectric layer 42b. The second outer electrode 43b is printed on the front face of the second dielectric layer 42b. The second inner electrode 44b is printed on the back face of the second dielectric layer 42b. Both the second outer electrode 43b and the second inner electrode 44b are made of the conductive material of the present invention. To a terminal 430b of the second outer electrode 43b and a terminal 440b of the second inner electrode 44b, a voltage is applied from outside.

The first members and the second members are fixed with the eight bolts 460 and the eight nuts 461, with the eight spacers 462 interposed therebetween. The sets of “the bolt 460, the nut 461, and the spacer 462” are arranged at predetermined intervals in the circumferential direction of the speaker 4. The bolt 460 penetrates from the front face of the first outer frame 40a to the front face of the second outer frame 40b. The nut 461 is screwed on the penetration end of the bolt 460. The spacer 462 is made of a resin and provided around the shank of the bolt 460. The spacers 462 secure a predetermined interval between the first inner frame 41a and the second inner frame 41b. The back face of the center part of the first dielectric layer 42a (the back side of the area on which the first diaphragm 45a is provided) is joined to the back face of the center part of the second dielectric layer 42b (the back side of the area on which the second diaphragm 45b is provided). Thus, the first dielectric layer 42a stores urging force in the direction shown by the white arrow Y1a in FIG. 6. Also, the second dielectric layer 42b stores urging force in the direction shown by the white arrow Y1b in FIG. 6.

Next, the movement of the speaker 4 will be described. Through the terminals 430a, 440a and the terminals 430b, 440b, a predetermined voltage (offset voltage) is applied to the first outer electrode 43a, the first inner electrode 44a, the second outer electrode 43b, and the second inner electrode 44b at the initial state (offset state). When the speaker 4 is operated, antiphase voltages are applied to the terminals 430a, 440a and the terminals 430b, 440b. For example, when an offset voltage of +1 V is applied to the terminals 430a, 440a, the thickness of the part of the first dielectric layer 42a, which is disposed between the first outer electrode 43a and the first inner electrode 44a, becomes small, and the part extends in the radial direction. Concurrently with this, the antiphase voltage (an offset voltage of −1 V) is applied to the terminals 430b, 440b. This increases the thickness of the part of the second dielectric layer 42b, which is disposed between the second outer electrode 43b and the second inner electrode 44b, and the part contracts in the radial direction. Consequently, the second dielectric layer 42b is elastically deformed in the direction shown by the white arrow Y1b in FIG. 6 by the own urging force while pulling the first dielectric layer 42a. In contrast, when an offset voltage of +1 V is applied to the terminals 430b, 440b and the antiphase voltage (an offset voltage of −1 V) is applied to the terminals 430a, 440a, the first dielectric layer 42a is elastically deformed in the direction shown by the white arrow Y1a in FIG. 6 by the own urging force while pulling the second dielectric layer 42b. This movement vibrates the first diaphragm 45a and the second diaphragm 45b, which consequently vibrates air and generates sound.

Next, advantageous effects of the speaker 4 will be described. According to the present embodiment, the first outer electrode 43a, the first inner electrode 44a, the second outer electrode 43b, and the second inner electrode 44b (hereinafter sometimes called “electrodes 43a, 44a, 43b, 44b”) are flexible and have excellent elasticity. Thus, the movements of the first dielectric layer 42a and the second dielectric layer 42b are less likely to be restricted by the electrodes 43a, 44a, 43b, 44b. Accordingly, the speaker 4 has good responsivity even in a low frequency region. Also, the electrodes 43a, 44a, 43b, 44b have high electric conductivity and have an electrical resistance that is less likely to increase even when the electrodes 43a, 44a, 43b, 44b are extended. In addition, the electrodes 43a, 44a, 43b, 44b are less likely to lose their resilience, to become cracked, or the like even when extension and contraction are repeated. Thus, deterioration in performance of the speaker 4 due to the electrodes 43a, 44a, 43b, 44b is less likely to occur. The speaker 4 therefore has excellent durability.

### EXAMPLES

Next, the present invention will be described in further detail with reference to Examples.

<Production of Conductive Material>

### Example 1

First, 70 parts by mass of an acrylic rubber polymer (“Paracron (registered trademark) KX-DR” manufactured by Negami Chemical Industrial Co., Ltd.), 30 parts by mass of a slide-ring molecule material (“SeRM (registered trademark) Elastomer S1000” manufactured by Advanced Softmaterials Inc.), and 2.6 parts by mass of polyisocyanate (“CORONATE (registered trademark) HL” manufactured by Nippon Polyurethane Industry Co., Ltd.) as the crosslinking agent were dissolved in methyl ethyl ketone as the solvent to prepare a polymer solution. Here, the slide-ring molecule material contains a modified polyrotaxane prepared by graft-bonding polycaprolactone to a ring molecule and a crosslinking agent. The polyrotaxane includes α-cyclodextrin as the ring molecule, polyethylene glycol as the linear molecule, and an adamantane group as the blocking group. Subsequently, 400 parts by mass of silver powder A (“Silcoat (registered trademark) AgC-224” manufactured by Fukuda Metal Foil & Powder Co., flaky, an average particle diameter of about 9 μm, a thickness of about 0.7 μm, an aspect ratio of 12.9) was added as the conductive agent to the polymer solution, and the whole was stirred and mixed to prepare a conductive paint. The conductive paint was applied to the surface of a substrate (release PET film) by bar coating. The coating was heated at 150° C. for 1 hour to be cured and to undergo crosslinking reaction. In this manner, a thin film-like conductive material having a thickness of 60 μm was produced. The produced conductive material is called the conductive material of Example 1.

### Example 2-1

A conductive material was produced in the same manner as in Example 1 except that carbon nanotubes (“VGCF (registered trademark)” manufactured by Showa Denko K. K., a fiber diameter of 150 nm, a length of 10 μm, an aspect ratio of 53) was used as the conductive agent in an amount of 23 parts by mass. The produced conductive material is called the conductive material of Example 2-1.

### Example 2-2

A conductive material was produced in the same manner as in Example 1 except that the carbon nanotubes (same as the above) were used as the conductive agent in an amount of 23 parts by mass, the acrylic rubber polymer was used in an amount of 50 parts by mass, the slide-ring molecule material was used in an amount of 50 parts by mass, and the crosslinking agent was used in an amount of 1.9 parts by mass. The produced conductive material is called the conductive material of Example 2-2.

### Example 3

A conductive material was produced in the same manner as in Example 1 except that silver powder B (“AG2-1C” manufactured by DOWA Electronics Materials Co., Ltd., spherical, an average particle diameter of about 1 μm and an aspect ratio of 1) was used as the conductive agent in an amount of 1,140 parts by mass. The produced conductive material is called the conductive material of Example 3.

### Comparative Example 1

A conductive material was produced in the same manner as in Example 1 except that no slide-ring molecule material was used, the amount of the acrylic rubber polymer was increased by the amount of the slide-ring molecule material, and the amount of the crosslinking agent was accordingly increased. The produced conductive material is called the conductive material of Comparative Example 1 (conductive agent: silver powder A).

### Comparative Example 2

A conductive material was produced in the same manner as in Examples 2-1 and 2-2 except that no slide-ring molecule material was used, the amount of the acrylic rubber polymer was increased by the amount of the slide-ring molecule material, and the amount of the crosslinking agent was accordingly increased. The produced conductive material is called the conductive material of Comparative Example 2 (conductive agent: carbon nanotubes).

### Comparative Example 3

A conductive material was produced in the same manner as in Example 3 except that no slide-ring molecule material was used, the amount of the acrylic rubber polymer was increased by the amount of the slide-ring molecule material, and the amount of the crosslinking agent was accordingly increased. The produced conductive material is called the conductive material of Comparative Example 3 (conductive agent: silver powder B).

<Evaluation Method>

The conduction characteristics and the tensile characteristics of each conductive material of Examples and Comparative Examples were evaluated. Each evaluation method will next be described.

[Conduction Characteristics]

The volume resistivity of a conductive material was determined in accordance with parallel terminal electrode method in JIS K6271 (2008). To determine the volume resistivity, a rectangle sheet-like test piece having a width of 10 mm, a length of 20 mm, and a thickness of 15 μm was used. The insulating resin holder used for holding the test piece was a commercially available silicone rubber sheet (manufactured by KUREHA ELASTOMER Co., Ltd.). The distance between electrodes was 10 mm in an unextended condition. The volume resistivity was measured at three different elongation ratios. In other words, the first measurement was carried out in natural conditions (unextended); the second measurement was carried out at an elongation ratio of 50%; and the third measurement was carried out at an elongation ratio of 100%. The ratio of change in the volume resistivity in the extended condition relative to the unextended condition was calculated in accordance with Equation (I):

Ratio of change in volume resistivity (%)=(R₁/R₀)×100 (I)

[R₀: the volume resistivity in the unextended condition; and R₁: the volume resistivity in an extended condition]

The elongation ratio is a value calculated in accordance with Equation (II):

Elongation ratio (%)=(ΔL/L₀)×100 (II)

[L₀: the gauge length of a test piece; and ΔL: an increase in the gauge length of the test piece by elongation]

[Tensile Characteristics]

Tensile test was carried out in accordance with JIS K6251 (2010), and the elongation at break (E_{b}) and the tensile stress at a predetermined elongation (Eₛ: modulus) were calculated. A test piece having the shape of dumbbell No. 2 was used, and the elongation rate was 100 mm/min. The modulus was determined at two elongation ratios of 50% and 100%.

<Evaluation Result>

Table 1 shows the evaluation results of each conductive material of Examples and Comparative Examples together with the raw material formulations. In Table 1, the unit of the amounts of raw materials is parts by mass.

TABLE 1

| | | | | | | Comparative | Comparative | Comparative |
|---|---|---|---|---|---|---|---|---|
| | | Example 1 | Example 2-1 | Example 2-2 | Example 3 | Example 1 | Example 2 | Example 3 |
| Elastomer | Acrylic rubber | 70 | 70 | 50 | 70 | 100 | 100 | 100 |
| Slide-ring | Modified polyrotaxane | 30 | 30 | 50 | 30 | — | — | — |
| molecule | | | | | | | | |
| Crosslinking | Polyisocyanate | 2.6 | 2.6 | 1.9 | 2.6 | 3.7 | 3.7 | 3.7 |
| agent | | | | | | | | |
| Conductive | Silver powder A (flaky) | 400 | — | — | — | 400 | — | — |
| agent | Silver powder B (spherical) | — | — | — | 1140 | — | — | 1140 |
| | Carbon nanotube | — | 23 | 23 | — | — | 23 | — |
| Conduction | Volume resistivity in unextended | 1.7 × 10⁻⁴ | 9.1 × 10⁻¹ | 6.9 × 10⁻¹ | 5.0 × 10⁻³ | 2.2 × 10⁻⁴ | 1.1 × 10⁰ | 6.1 × 10⁻³ |
| characteristics | condition [Ω · cm] | | | | | | | |
| | Volume resistivity at 50% | 578 | 346 | 154 | 1613 | 1796 | 627 | 19672 |
| | elongation [%] | | | | | | | |
| | Volume resistivity at 100% | 1197 | 966 | 269 | Broken | 7914 | 6509 | Broken |
| | elongation [%] | | | | | | | |
| Tensile | 50% modulus [MPa] | 1.30 | 1.37 | 0.84 | 0.83 | 1.79 | 2.88 | 1.10 |
| characteristics | 100% modulus [MPa] | 1.22 | 1.47 | 0.77 | Broken | 1.99 | 3.13 | Broken |
| | Elongation at break [%] | 241 | 408 | 253 | 70 | 228 | 336 | 60 |

First, Example 1 and Comparative Example 1, in which the flaky silver powder A was used as the conductive agent, are compared. As shown in Table 1, both volume resistivities are substantially the same in the unextended condition. However, the conductive material of Example 1 in the extended condition showed a significantly smaller ratio of change in the volume resistivity. The conductive material of Example 1 also had a smaller modulus. These results suggest that the stress concentration is reduced in the conductive material of Example 1 in the extended condition. The conductive material of Example 1 also had a larger elongation at break.

Next, Examples 2-1 and 2-2 and Comparative Example 2, in which the carbon nanotubes were used as the conductive agent, are compared. As shown in Table 1, the conductive material of Example 2-2, in which the slide-ring molecule material was contained in a larger amount, had a slightly smaller volume resistivity in the unextended condition than the conductive material of Example 2-1. However, there is no noticeable difference in the volume resistivity in the unextended condition among the conductive materials of Examples 2-1 and 2-2 and Comparative Example 2. In contrast, the conductive materials of Examples 2-1 and 2-2 in the extended condition had significantly smaller ratios of change in the volume resistivity than the conductive material of Comparative Example 2 in the extended condition. The conductive materials of Examples 2-1 and 2-2 also had a smaller modulus. In particular, the conductive material of Example 2-2, in which the slide-ring molecule material was contained in a larger amount, had a larger decrease in the modulus than the conductive material of Example 2-1. These results suggest that the stress concentration is reduced in the conductive materials of Examples 2-1 and 2-2 in the extended condition. The conductive material of Example 2-1 had a larger elongation at break than the conductive material of Comparative Example 2, but the conductive material of Example 2-2 had a smaller elongation at break than the conductive material of Comparative Example 2. This is supposed to be because an increase in the amount of the slide-ring molecule material lowered the flexibility.

Next, Example 3 and Comparative Example 3, in which the spherical silver powder B was added as the conductive agent, are compared. As shown in Table 1, both volume resistivities are substantially the same in the unextended condition. However, the conductive material of Example 3 had a significantly smaller ratio of change in the volume resistivity at an elongation ratio of 50%. The conductive material of Example 3 also had a smaller modulus at an elongation ratio of 50%. These results suggest that the stress concentration is reduced in the conductive material of Example 3 in the extended condition. The conductive materials of Example 3 and Comparative Example 3 contained a large amount of silver powder B. The conductive material of Example 3 had a larger elongation at break. However, both conductive materials were broken when extended at an elongation ratio of 100%.

The above results reveal that the conductive material of the present invention is flexible and has excellent extensibility and high electric conductivity. In addition, the conductive material of the present invention has an electric conductivity that is less likely to decrease even when the conductive material is extended.

### INDUSTRIAL APPLICABILITY

The conductive material of the present invention is preferably used as electrodes and wirings for flexible transducers such as actuators, sensors, speakers, and power generation devices. The conductive material is also preferably used as wirings of flexible wiring boards used for the control of moving parts of robots and industrial machines, wearable devices, flexible displays, and other devices. The conductive material is still preferably used for electromagnetic wave shields and electrically conductive adhesives. The conductive material of the present invention can be used for electrodes and wirings, thereby improving the durability of electronic devices mounted in flexible members such as moving parts of robots, care equipment, and interior members of transportation equipment.

1. A conductive material characterized by comprising:
an elastomer; and
a conductive agent contained in the elastomer, wherein
the elastomer has a crosslinked structure through a slide-ring molecule having a ring molecule and a linear molecule that passes through an opening of the ring molecule and is included in the ring molecule,
at least a part of polymer chains of the elastomer is crosslinked with the ring molecule, and
as the ring molecule moves along the linear molecule, a crosslinking point moves.

2. The conductive material according to claim 1, wherein
the slide-ring molecule is polyrotaxane.

3. The conductive material according to claim 1, wherein
the ring molecule has a reactive group, and
the crosslinked structure is formed through a crosslinking reaction of the reactive group and a raw material polymer of the elastomer.

4. The conductive material according to claim 1, wherein
the elastomer is one or more selected from acrylic rubber, silicone rubber, urethane rubber, urea rubber, fluororubber, or thermoplastic elastomers.

5. The conductive material according to claim 1, wherein
the conductive agent is one or more conductive agents selected from metal particles, metal nanowires, carbon nanotubes, carbon black, graphite, and graphene.

6. A transducer characterized by comprising:
an electrostrictive layer made of a polymer;
a plurality of electrodes with the electrostrictive layer interposed therebetween, and
wirings connecting to the corresponding electrodes, wherein
either one or both of the electrodes and the wirings are formed of the conductive material as claimed in claim 1.
